(19) United States
(12) Patent Application Publication
(10) Pub. No.: US 2005/0157479 A1
(43) Pub. Date: Jul. 21, 2005

(54) Bus device insertion and removal system

(76) Inventor: Douglas Todd Hayden, San Diego, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/759,819

(22) Filed: Jan. 16, 2004

(51) Int. Cl. H05K 7/10

(52) U.S. Cl. 361/788; 710/301; 710/302

(57) ABSTRACT

Embodiments of the present invention are used in systems. In one embodiment, the system comprises a bus comprising signal lines and a device configured to be inserted onto and removed from the bus through contacts. The contacts are configured to provide at different times during insertion and removal contact between a pre-charge circuit and one of the signal lines, and a low-impedance across the pre-charge circuit.

### BACKGROUND

An increasing number of electronic systems require a high degree of reliability, including very limited downtime. Loss or failure of one system, such as a control system or a memory system, typically requires replacement of the failed system to maintain redundancy and reliability of the associated electronic system. Due to the limited downtime requirement, replacing failed systems is often accomplished by hot removal and insertion of devices on a bus of the electronic system. Hot removal and insertion of devices on a bus is referred to as hot swapping devices. Hot swapping devices, includes removing a device from and inserting another device onto an operating bus.

One type of bus known in the art is a two wire serial bus including two signal lines, referred to as a serial data (SDA) line and a serial clock (SCL) line. The two wire serial bus transmits both addresses and by-directional data over the two signal lines. Power, a reference voltage, and the two signal lines are used to link devices, such as host systems and modules together. The modules can include systems such as control systems, memory systems and keypads. One such two wire serial bus is the Phillips inter-integrated circuit (I2C) bus.

A system using a two wire serial bus includes devices connected in parallel. Typically, the SDA and SCL signal lines are attached to master pull-up resistors and open drain outputs of the devices. The devices create signals on the SDA and SCL lines by pulling the signal lines to a low voltage level.

Hot swapping unpowered devices on the two wire serial bus can cause signal degradation. The unpowered devices sink current from the master pull-up resistors through resistive loads and transient suppression diodes connected to unpowered voltage supplies. In addition, other subtle sources of signal degradation exist, such as instantaneous charging of node capacitance associated with the unpowered device. Node capacitance includes connector capacitance and printed circuit board capacitance. Signal degradation of valid SDA and SCL signals can lead to false data or clocking seen by devices on the bus.

### SUMMARY

Embodiments of the present invention are used in systems. In one embodiment, the system comprises a bus comprising signal lines and a device configured to be inserted onto and removed from the bus through contacts. The contacts are configured to provide at different times during insertion and removal contact between a pre-charge circuit and one of the signal lines, and a low-impedance across the pre-charge circuit.

### BRIEF DESCRIPTION OF THE DRAWINGS

Embodiments of the invention are better understood with reference to the following drawings. The elements of the drawings are not necessarily to scale relative to each other. Like reference numerals designate corresponding similar parts.

FIG. 1 is a diagram illustrating an exemplary embodiment of an electronic system, according to the present invention.

FIG. 2 is a diagram illustrating an exemplary embodiment of a connector for hot swapping a module on a bus.

FIG. 3 is a diagram illustrating an exemplary embodiment of a connector, as a module is connected to a bus.

FIG. 4 is a diagram illustrating an exemplary embodiment of a connector, as a module is connected to power from a bus.

FIG. 5 is a diagram illustrating an exemplary embodiment of a connector, as a module is connected to a bus to pre-charge module SDA and SCL contacts.

FIG. 6 is a diagram illustrating an exemplary embodiment of a connector with a module completely connected to a bus.

FIG. 7 is a flow diagram illustrating an exemplary insertion of a module onto a bus.

FIG. 8 is a flow diagram illustrating an exemplary removal of a module from a bus.

### DETAILED DESCRIPTION

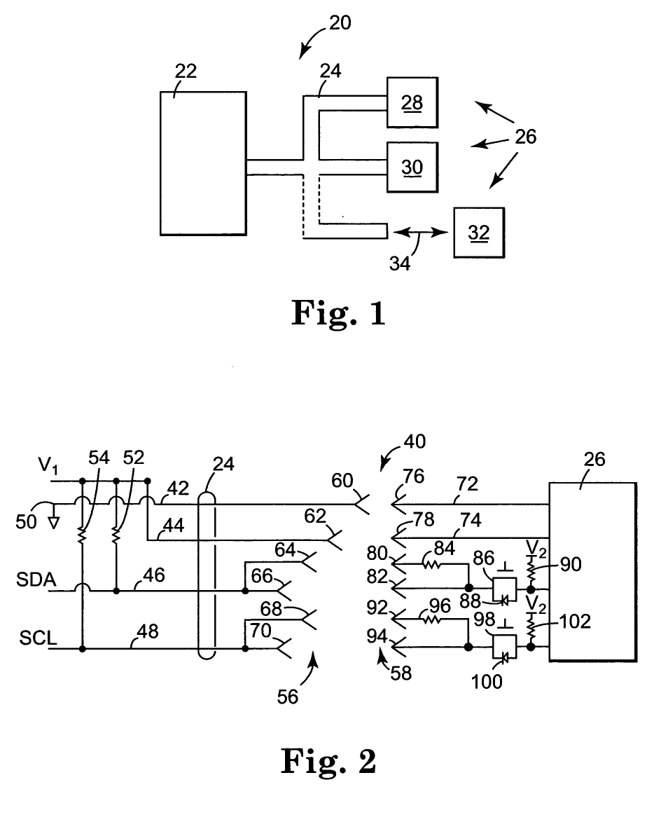

FIG. 1 is a diagram illustrating an exemplary embodiment of an electronic system 20, according to the present invention. The electronic system 20 includes a host system 22, a bus 24 and modules, indicated at 26. The modules 26 include a control module 28, a memory module 30 and a peripheral module, such as a keypad, indicated at 32. The host 22 and modules 26 can be inserted onto and removed from bus 24, as indicated at 34. In other embodiments, the electronic system does not include a host system, such as host system 22. Instead, the electronic system is made up entirely of modules, such as modules 26.

In the exemplary embodiment, the host 22 and modules 26 are electrically coupled to and decoupled from bus 24 through connectors. The connectors reduce or eliminate voltage glitches on bus 24 as host 22 and modules 26 are inserted onto and removed from bus 24. The host 22 and modules 26 are connected to bus 24 through connectors that have staggered connections. The staggered connections make contact at different times as host 22 and modules 26 are inserted onto and removed from bus 24. In addition, pre-charge circuits are included to pre-charge lines leading to host 22 and modules 26. The pre-charge circuits charge the host 22 and module 26 lines to bus signal levels before a low-impedance or short-circuit couples the host 22 and module 26 lines to the bus signal lines, as the host 22 and modules 26 are inserted onto bus 24. The pre-charge circuits include resistive elements for reducing current drawn through master pull-up resistors attached to bus 24. A low-impedance or short-circuit and words such as shorted and shorting, as used herein, refer to any impedances from zero ohms up to an impedance level that allows the host 22 and modules 26 to provide a low logic level on bus 24.

Host 22 is electrically coupled to bus 24 by inserting host 22 on bus 24. The host 22 sends and receives signals through bus 24 to communicate with modules 26 that are electrically coupled to bus 24. In the event host 22 fails or stops functioning properly, host 22 is removed from bus 24 and repaired and reinserted or replaced.

Host 22 is a primary system controller that provides system functions for electronic system 20. The host 22 includes a microprocessor and memory that stores an operating system for performing system functions. In other embodiments, host 22 can include other suitable control circuits, such as one or more microcontrollers or state machine control circuits.

The modules 26 are electrically coupled to bus 24 by inserting the modules 26 onto bus 24. The modules 26 send and receive signals through bus 24 to communicate with each other and host 22. In the event one of the modules 26 stops functioning properly, the failed module 26 is removed and repaired and reinserted or replaced.

The control module 28 includes a controller that provides one or more functions to expand the capabilities of host 22 and electronic system 20. The control module 28 can provide any suitable function(s), including video display functions, audio functions and security functions. Control module 28 includes a microprocessor and memory that stores an operating system for performing the functions of the control module 28. The functions of control module 28 include communicating with host 22 and other modules 26, as well as the specialized functions of the control module 28. In other embodiments, control module 28 can include any suitable control circuits, such as one or more microcontrollers or state machine control circuits.

The memory module 30 includes a memory controller and memory. The memory controller communicates through bus 24 with other modules 26 and host 22 to upload data from and download data to the memory in memory module 30. The memory in memory module 30 can be any suitable memory, such as a magnetic disc memory or a solid-state memory including random access memory (RAM), electrically erasable programmable read-only memory (EEPROM), Flash EEPROM and magnetic random access memory (MRAM). In other embodiments, the memory module can include a memory interface to storage media such as magnetic tapes and optical discs. Optical disc storage media includes compact discs (CDs) and digital video discs (DVDs).

The peripheral module 32 is another type of module 26 that can be inserted and removed from bus 24, indicated at 34. One type of peripheral module 32 is a keypad that communicates through bus 24 to provide user input into electronic system 20. The keypad can be used to control operation of host 22 and modules 26, such as a control module 28 that is a security system. A peripheral module 32 can include a microprocessor or controller and memory that stores an operating system to provide the functions of the peripheral module 32 and communicate through bus 24 with host 22 and other modules 26.

Bus 24 is a two wire serial bus, such as Phillips inter-integrated circuit bus, that electrically couples host 22 and modules 26 in a parallel bus structure. In the exemplary embodiment, bus 24 is part of a backplane. In other embodiments, bus 24 can be part of any suitable structure, including a set of cables connected together in parallel or a mid-plane structure.

In the exemplary embodiment, only one host 22, control module 28, memory module 30 and peripheral module 32 are shown to simplify the illustration. In practice, any suitable number of modules 26 and more than one host 22 can be inserted onto bus 24. In one suitable embodiment, an electronic system includes primary and secondary systems including a primary and a secondary host 22, a primary and a secondary control module 28 and a primary and a secondary memory module 30. The secondary systems are redundant systems that mirror operation of the primary systems. In the event a primary system fails, the corresponding secondary system takes over to maintain operation of the overall electronic system. For example, in the event the primary host system fails, the secondary host system takes over operation of the electronic system. The primary host system is removed from bus 24 and the repaired primary host system or another host system is hot swapped onto bus 24. The secondary host system takes over as the primary host system and the new or reinstalled host system acts as the secondary host system. The primary and secondary control modules 28 and the primary and secondary memory modules 30 can also be hot swapped to limit system downtime and maintain redundant system operation.

FIG. 2 is a diagram illustrating an exemplary embodiment of a connector 40 for hot swapping module 26 on bus 24. Module 26 is any one of the modules 26 including control module 28, memory module 30 and peripheral module 32. In addition, host 22 is inserted onto and removed from bus 24 with a connector similar to connector 40.

The two wire serial bus 24 includes a reference line 42, a power line 44, an SDA signal line 46 and an SCL signal line 48. The reference line 42 is electrically coupled to ground at 50, and power line 44 is electrically coupled to voltage V₁. Voltage V₁ and ground 50 are provided by host 22. The SDA signal line 46 and SCL signal line 48 are electrically coupled to master pull-up resisters 52 and 54. Resistor 52 is electrically coupled between SDA signal line 46 and power line 44, and resistor 54 is electrically coupled between SCL signal line 48 and power line 44. Voltage V₁ pulls the SDA and SCL signal lines 46 and 48 toward a high voltage level through master pull-up resistors 52 and 54. The host 22 and modules 26 electrically coupled to bus 24 pull the SDA and SCL signal lines 46 and 48 to a low voltage level with open collector or open drain transistors to provide signals on bus 24.

Connector 40 includes a female side 56 and a male side 58. The female side 56 is electrically coupled to bus 24 and the male side 58 is electrically coupled to module 26. The contacts on female side 56 are physically staggered and the contacts on male side 58 are aligned in a column. The contacts on female side 56 and male side 58 are arranged to make contact in a predetermined order as module 26 is inserted onto bus 24, and to release contact in the reverse order as module 26 is removed from bus 24. In other embodiments, single pin connectors can be configured to include multiple contacts. Also, in other embodiments, the female and male sides 56 and 58 can be switched, such that male side 58 is electrically coupled to bus 24 and female side 56 is electrically coupled to module 26. In addition, in other embodiments, male side 58 can be staggered and female side 56 can be aligned in a column, or both male side 58 and female side 56 can be staggered. In all embodiments, the contacts are arranged to make contact and release contact in an ordered sequence.

In the exemplary embodiment, female side 56 of connector 40 includes a reference line contact 60, a power line contact 62, an SDA pre-charge contact 64, an SDA contact 66, an SCL pre-charge contact 68 and an SCL contact 70. The reference line contact 60 is electrically coupled to reference line 42 and ground 50. The power line contact 62 is electrically coupled to power line 44 and voltage V₁. The SDA pre-charge contact 64 and SDA contact 66 are electrically coupled to SDA signal line 46. The SCL pre-charge contact 68 and SCL contact 70 are electrically coupled to SCL signal line 48.

The reference line contact 60 is located in front of power line contact 62 to make contact with male side 58 before power line contact 62 makes contact with male side 58, as module 26 is inserted onto bus 24. The reference line contact 60 makes contact with male side 58 to provide a common reference signal between module 26 and bus 24. The power line contact 62 makes contact with male side 58 to provide power to module 26.

In other embodiments, power line contact 62 makes contact with male side 58 before reference line contact 60 as module 26 is inserted on bus 24, or power line contact 62 is not included in connector 40. In the latter situation, module 26 receives power from another source or provides power to itself through an on-board power supply.

In the exemplary embodiment, SDA pre-charge contact 64 is positioned to make contact with male side 58 at essentially the same time as SCL pre-charge contact 68. The SDA pre-charge contact 64 and SCL pre-charge contact 68 are located behind power line contact 62. The SDA pre-charge contact 64 connects SDA signal line 46 to male side 58 of connector 40, and the SCL pre-charge contact 68 connects SCL signal line 48 to male side 58 of connector 40. In other embodiments, SDA and SCL pre-charge contacts 64 and 68 do not make contact with male side 58 at the same time. Instead, SDA and SCL pre-charge contacts 64 and 68 are staggered to make contact with male side 58 at different times.

In the exemplary embodiment, the SDA pre-charge contact 64 and SCL pre-charge contact 68 make contact with the male side 58 after the power line contact 62, as module 26 is inserted onto bus 24. In other embodiments, power line contact 62 makes contact with male side 58 as SDA pre-charge contact 64 and SCL pre-charge contact 68 make contact with male side 58, as module 26 is inserted onto bus 24. In any situation, SDA and SCL pre-charge contacts 64 and 68 make contact with male side 58 before SDA and SCL contacts 66 and 70 as module 26 is inserted onto bus 24.

In the exemplary embodiment, SDA contact 66 makes contact with male side 58 at essentially the same time as SCL contact 70. The SDA and SCL contacts 66 and 70 are located behind SDA and SCL pre-charge contacts 64 and 68. The SDA contact 66 connects SDA signal line 46 to male side 58 and the SCL contact 70 connects SCL signal line 48 to male side 58. In other embodiments, SDA and SCL contacts 66 and 68 do not make contact with male side 58 at the same time. Instead, SDA and SCL contacts 66 and 70 are staggered to make contact at different times.

The male side 58 of connector 40 includes a module reference line contact 76, a module power line contact 78, a module SDA pre-charge contact 80, a module SDA contact 82, a module SCL pre-charge contact 92 and a module SCL contact 94. The module reference line contact 76 is electrically coupled to a module reference line 72 that is electrically coupled to module 26. The module power line contact 78 is electrically coupled to a module power line 74 that is electrically coupled to module 26.

The module SDA pre-charge contact 80 is electrically coupled to an SDA pre-charge resistor 84. The SDA pre-charge resistor 84 is electrically coupled between module SDA pre-charge contact 80 and module SDA contact 82. The module SDA contact 82 and SDA pre-charge resistor 84 are electrically coupled to the drain of a field effect transistor (FET) switch 86. The source of FET 86 is electrically coupled to module 26 with the FET body diode 88 reversed biased from connector 40 to module 26. The gate of FET 86 is electrically coupled to module 26 to switch FET 86 on (conducting) or off (non-conducting). A module SDA pull-up resistor 90 is electrically coupled to the source of FET 86. The SDA pull-up resistor is pulled to voltage V₂ provided by module 26.

The module SCL pre-charge contact 92 is electrically coupled to an SCL pre-charge resistor 96 that is electrically coupled between the module SCL pre-charge contact 92 and module SCL contact 94. The module SCL contact 94 and SCL pre-charge resistor 96 are electrically coupled to the drain of a FET switch 98. The source of FET 98 is electrically coupled to module 26 with the FET body diode 100 reversed bias from connector 40 to module 26. The gate of FET 98 is electrically coupled to module 26 to switch FET 98 on (conducting) or off (non-conducting). A module SCL pull-up resistor 102 is electrically coupled to the source of FET 98. The SCL pull-up resistor 102 is pulled to voltage V₂ provided by module 26.

As module 26 is inserted on bus 24, male side 58 of connector 40 makes contact with female side 56 to provide ground and then power to module 26. In addition, module SDA and SCL contacts 82 and 94 are pre-charged to voltages on SDA and SCL signal lines 46 and 48 through SDA and SCL pre-charge resistors 84 and 96, before being shorted to SDA and SCL signal lines 46 and 48. After module SDA and SCL contacts 82 and 94 are shorted to SDA and SCL signal lines 46 and 48, FET 86 and FET 98 are turned on to conduct and enable module 26 to communicate on bus 24.

As module 26 is removed from bus 24, FET 86 and FET 98 are turned off, and male side 58 of connector 40 separates from female side 56. FET 86 and FET 98 are turned off by pushing a release button on module 26. With FET 86 and FET 98 off, module SDA and SCL contacts 82 and 94 present high impedances to bus 24. The short circuits between SDA signal line 46 and module SDA contact 82 and between SCL signal line 48 and module SCL contact 94 open as male side 58 separates from female side 56. Next, the module SDA and SCL pre-charge contacts 80 and 92 are pulled away from female side 56 to disengage SDA and SCL signal lines 46 and 48 from male side 58. Finally, power and then ground are removed to disengage module 26 from bus 24 completely.

In other embodiments, FET 86 and FET 98 are not turned off as module 26 is removed from bus 24. Instead FET 86 and FET 98 are left on as male side 58 of connector 40 separates from female side 56. The low-impedances between SDA signal line 46 and module SDA contact 82 and between SCL signal line 48 and module SCL contact 94 open as male side 58 separates from female side 56. The voltages on the module SDA contact 82 and module SCL contact 94 remain high or rise toward a high voltage level. Next, module SDA and SCL pre-charge contacts 80 and 92 are pulled away from female side 56 to disengage SDA and SCL signal lines 46 and 48 from male side 58. Power and then ground are removed to completely disengage module 26 from bus 24.

FIG. 3 is a diagram illustrating an exemplary embodiment of connector 40, as module 26 is connected to bus 24. Module 26 and male side 58 of connector 40 are aligned with bus 24 and female side 56 of connector 40. The reference line contact 60 on female side 56 is aligned with module reference line contact 76 on male side 58. The power line contact 62 on female side 56 is aligned with module power line contact 78 on male side 58. SDA pre-charge contact 64 is aligned with module SDA pre-charge contact 80, and SDA contact 66 is aligned with module SDA contact 82. In addition, SCL pre-charge contact 68 is aligned with module SCL pre-charge contact 92, and SCL contact 70 is aligned with module SCL contact 94.

As module 26 is inserted on bus 24, male side 58 begins to make contact with female side 56. The first contacts to meet are reference line contact 60 and module reference line contact 76. The reference line contact 60 and module reference line contact 76 make contact to provide a common reference voltage to bus 24 and module 26. In the exemplary embodiment, the common reference voltage is ground. In other embodiments, any suitable voltage, such as one or two volts, can be used as the common reference voltage.

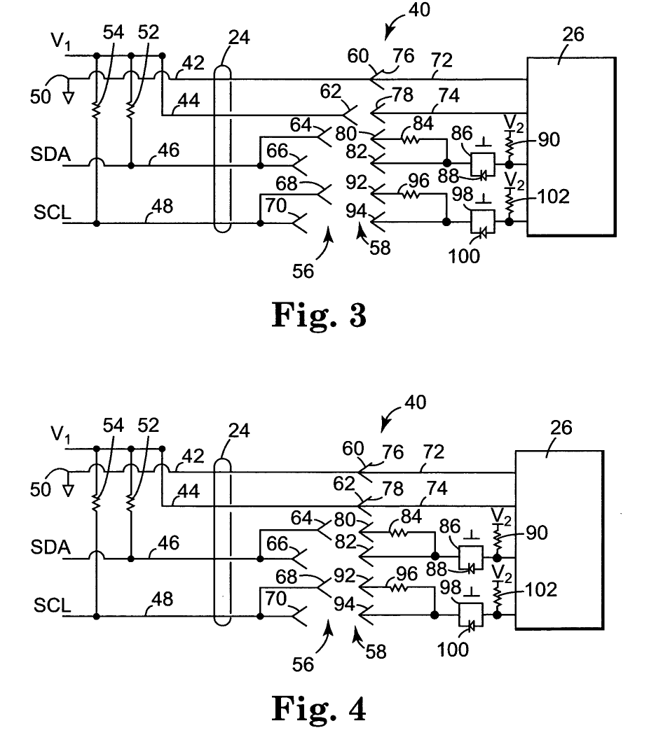

FIG. 4 is a diagram illustrating the exemplary embodiment of connector 40, as module 26 is connected to power from bus 24. The reference line contact 60 and module reference line contact 76 are electrically coupled together. The power line contact 62 is aligned with module power line contact 78. As module 26 is inserted onto bus 24, power line contact 62 and module power line contact 78 are electrically coupled to provide power to module 26.

Module 26 powers up and provides known states to the gate and source of FET 86 and the gate and source of FET 98. In addition, module 26 provides voltage V₂ to module SDA and SCL pull-up resistors 90 and 102. Module 26 includes an open drain transistor at the source of FET 86 and an open drain transistor at the source of FET 98. Module 26 shuts off these open drain transistors and voltage V₂ pulls the source of FET 86 and the source of FET 98 to a high voltage. Module 26 provides gate voltages to the gates of FET 86 and FET 98 to switch the FETs 86 and 98 off (non-conducting). With FET 86 and FET 98 switched off, the drains of FET 86 and FET 98 present high impedances to module SDA and SCL pre-charge contacts 80 and 92 and module SDA and SCL contacts 82 and 94.

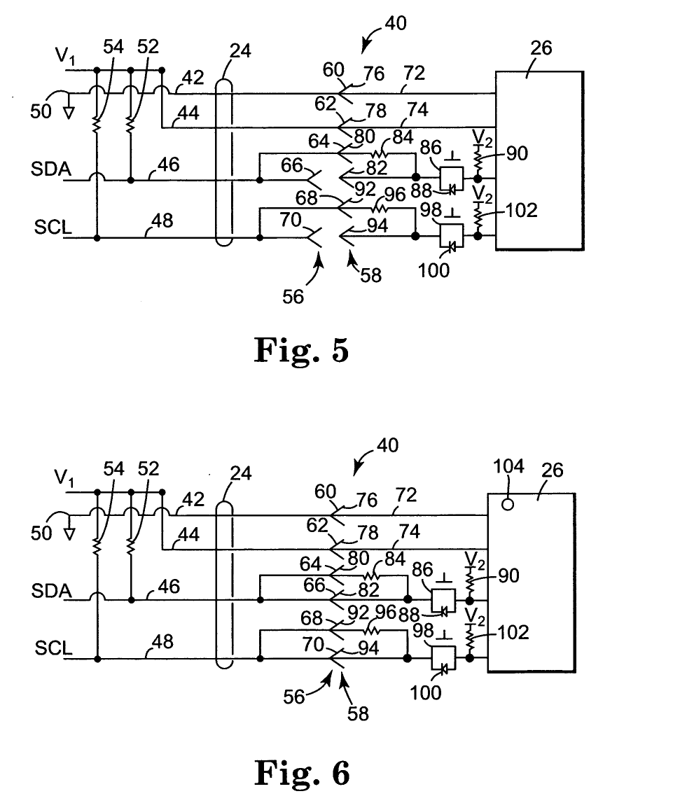

FIG. 5 is a diagram illustrating the exemplary embodiment of connector 40, as module 26 is connected to bus 24 to pre-charge module SDA and SCL contacts 82 and 94. The module SDA and SCL contacts 82 and 94 have nodal capacitances. The nodal capacitance at module SDA contact 82 includes capacitance from connector 40, FET 86 and printed circuit board capacitances. The nodal capacitance at module SCL contact 94 includes capacitance from connector 40, FET 98 and printed circuit board capacitances. The SDA pre-charge contact 64 is electrically coupled to module SDA pre-charge contact 80 to charge module SDA contact 82 and the associated nodal capacitance to the voltage on SDA signal line 46. The module SDA contact 82 and associated nodal capacitance are charged through module SDA pre-charge resistor 84 to reduce current spikes and voltage glitches on SDA signal line 46. The SCL pre-charge contact 68 is electrically coupled to module SCL pre-charge contact 92 to charge module SCL contact 94 and the associated nodal capacitance to the voltage on SCL signal line 48. The module SCL contact 94 and associated nodal capacitance are charged through module SCL pre-charge resistor 96 to reduce current spikes and voltage glitches on SCL signal line 48.

As module 26 is connected to bus 24, reference line contact 60 is electrically coupled to module reference line contact 76, and power line contact 62 is electrically coupled to module power line contact 78. Bus 24 provides voltage V₁ to module 26 and module 26 provides voltage V₂ to pull-up resistors 90 and 102. In addition, module 26 provides gate voltages to FET 86 and FET 98 to turn off FET 86 and FET 98 and provide high impedances to bus 24. The bus 24 is powered and operating to provide voltages on SDA signal line 46 and SCL signal line 48. The voltage on SDA signal line 46 is at SDA pre-charge contact 64 and the voltage on SCL signal line 48 is at SCL pre-charge contact 68.

As module 26 is further connected to bus 24, SDA pre-charge contact 64 is electrically coupled to module SDA pre-charge contact 80, and SCL pre-charge contact 68 is electrically coupled to module SCL pre-charge contact 92. As SDA pre-charge contact 64 makes contact with module SDA pre-charge contact 80, the voltage on SDA signal line 46 creates a charge current through SDA pre-charge resistor 84. The charge current through SDA pre-charge resistor 84 charges module SDA contact 82 and the associated nodal capacitance to the voltage level on SDA signal line 46. The SDA pre-charge resistor 84 limits the charge current to reduce current spikes and voltage glitches on SDA signal line 46. As SCL pre-charge contact 68 makes contact with module SDA pre-charge contact 92, the voltage on SCL signal line 48 creates a charge current through SCL pre-charge resistor 96. The charge current through SCL pre-charge resistor 96 charges module SCL contact 94 and the associated nodal capacitance to the voltage level on SCL signal line 48. The SCL pre-charge resistor 96 limits the charge current to reduce current spikes and voltage glitches on SCL signal line 48.

As a result, the voltage on module SDA contact 82 is equal to the voltage on SDA signal line 46, and the voltage on module SCL contact 94 is equal to the voltage on SCL signal line 48. The module SDA and SCL contacts 82 and 94 and the associated nodal capacitances are charged to the voltage levels on SDA and SCL signal lines 46 and 48, before SDA contact 66 is shorted to module SDA contact 82 and before SCL contact 70 is shorted to module SCL contact 94. In one example insertion, it takes 22 microseconds to charge 100 pf of nodal capacitance to a high voltage level through a 100 kilo-ohm pre-charge resistor, and it takes 1.6 milliseconds to short a first set of connector pins and a second set of connector pins having 0.75 mm pin stagger between the first and second sets and being inserted at 3 ft/second. The time between 22 microseconds and 1.6 milliseconds is a wide time margin for equalizing the voltage levels on module SDA and SCL contacts 82 and 94 with the voltage levels on SDA and SCL signal lines 46 and 48, before SDA contact 66 is shorted to module SDA contact 82 and SCL contact 70 is shorted to module SCL contact 94.

In other embodiments, FET 86 and FET 98 are not included and the nodal capacitances at module SDA and SCL contacts 82 and 94 include capacitance associated with printed circuit board traces leading up to module 26 and the input/output transistors of module 26. Also, in the exemplary embodiment, module SDA pre-charge contact 80 and SDA pre-charge contact 64 make contact at about the same time as module SCL pre-charge contact 92 and SCL pre-charge contact 68. In other embodiments, the SDA and SCL contacts can be staggered to be electrically coupled at different times.

FIG. 6 is a diagram illustrating the exemplary embodiment of connector 40 with module 26 completely connected to bus 24. As module 26 is further connected to bus 24, SDA contact 66 is electrically coupled to module SDA contact 82, and SCL contact 70 is electrically coupled to module SCL contact 94. The module SDA contact 82 is shorted to SDA signal line 46 across SDA pre-charge resistor 84. The module SCL contact 94 is shorted to SCL signal line 48 across SCL pre-charge resistor 96. To communicate on bus 24, module 26 provides gate voltages to the gates of FET 86 and FET 98 to turn them on. FET 86 and FET 98 conduct to enable module 26 to communicate on bus 24.

To remove module 26 from bus 24, a button 104 is pushed to turn off FET 86 and FET 98 and provide high impedance drains to bus 24. As module 26 is pulled away from bus 24, the insertion sequence is reversed. The SDA contact 66 is separated from module SDA contact 82, and the SCL contact 70 is separated from module SCL contact 94. The voltages on the module SDA and SCL contacts 82 and 94 remain equal to the corresponding voltages on the SDA and SCL signal lines 46 and 48. No voltage changes or glitches are provided to bus 24 as SDA and SCL contacts 66 and 70 separate from module SDA and SCL contacts 82 and 94. Next, SDA pre-charge contact 64 is separated from module SDA pre-charge contact 80, and SCL pre-charge contact 68 is separated from module SCL pre-charge contact 92. With FET 86 and FET 98 turned off, no voltage changes or glitches are provided to SDA signal line 46 and SCL signal line 48. To complete removing module 26 from bus 24, power line contact 62 is separated from module power line contact 78 to power down module 26, and reference line contact 60 is separated from module reference line contact 76.

In other embodiments, module 26 does not include button 104 and FET 86 and FET 98 are not turned off as module 26 is removed from bus 24. Instead FET 86 and FET 98 are left on as module 26 is pulled away from bus 24. The SDA contact 66 is separated from module SDA contact 82, and the SCL contact 70 is separated from module SCL contact 94. The voltages on module SDA and SCL contacts 82 and 94 remain high or rise toward a high voltage level. Next, SDA pre-charge contact 64 is separated from module SDA pre-charge contact 80, and SCL pre-charge contact 68 is separated from module SCL pre-charge contact 92. To complete removing module 26 from bus 24, power line contact 62 is separated from module power line contact 78 to power down module 26, and reference line contact 60 is separated from module reference line contact 76.

In other embodiments, FET 86 and FET 98 are not provided between module 26 and module SDA and SCL contacts 82 and 94. Instead module 26 is connected directly to SDA and SCL signal lines 46 and 48. If module 26 is operating or pulling one of the signal lines 46 and 48 to a low voltage level as it is removed from bus 24, separation of module 26 from SDA and SCL signal lines 46 and 48 may include a voltage rise on SDA and SCL signal lines 46 and 48. However, no current spikes or voltage glitches are provided to SDA and SCL signal lines 46 and 48 due to the separation. In any embodiment, if module 26 is operating to pull SDA signal line 46 and/or SCL signal line 48 low as module 26 is removed from bus 24, communications stop and the host 22 and modules 26 remaining on bus 24 resolve the interrupted communication to continue operation.

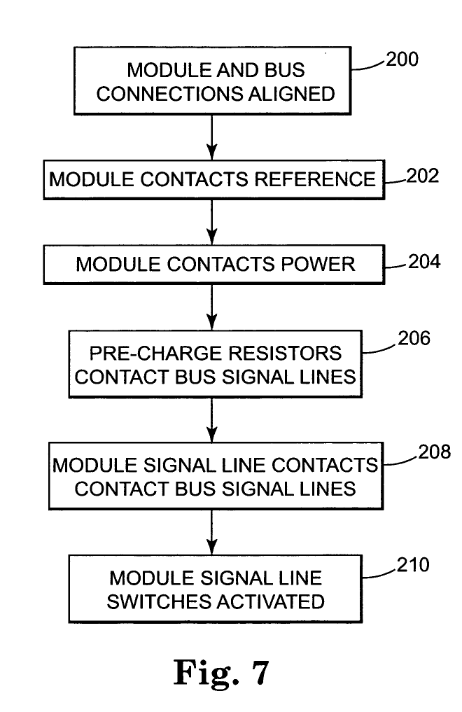

FIG. 7 is a flow diagram illustrating an exemplary insertion of module 26 onto bus 24. At 200, module 26 and bus 24 are positioned to align the contacts on male side 58 with the contacts on female side 56. At 202, as module 26 is connected to bus 24, module reference line contact 76 is electrically coupled to bus reference line contact 60. The bus reference line 42 provides a common ground to bus 24 and module 26 through reference line contact 60 and module reference line contact 76. At 204, power line contact 62 is electrically coupled to module power line contact 78 to provide voltage V₁ to module 26. Module 26 powers up and provides high impedance outputs to the sources of FET 86 and FET 98. In addition, module 26 provides voltage V₂ to SDA and SCL pull-up resistors 90 and 102, and gate voltages to FET 86 and FET 98. The module 26 switches FET 86 and FET 98 off to provide high impedance drains to bus 24.

At 206, module 26 is further inserted onto bus 24 to connect SDA and SCL pre-charge resistors 84 and 96 to SDA and SCL signal lines 46 and 48, respectively. The SDA pre-charge contact 64 is electrically coupled to module SDA pre-charge contact 80, and the SCL pre-charge contact 68 is electrically coupled to module SCL pre-charge contact 92. The SDA and SCL signal lines 46 and 48 pre-charge module SDA and SCL contacts 82 and 94 and associated nodal capacitances to voltage levels on the SDA and SCL signal lines 46 and 48 through SDA and SCL pre-charge resistors 84 and 96.

At 208, module 26 is further inserted onto bus 24 to complete the connection. SDA contact 66 is electrically coupled to module SDA contact 82, and SCL contact 70 is electrically coupled to module SCL contact 94. The SDA signal line 46 is shorted across SDA pre-charge resistor 84 to the drain of FET 86. SCL signal line 48 is shorted across SCL pre-charge resistor 96 to the drain of FET 98. At 210, module 26 provides a gate voltage to the gate of FET 86 and a gate voltage to the gate of FET 98 to switch on FET 86 and FET 98. FET 86 and FET 98 provide conductive paths between module 26 and SDA and SCL signal lines 46 and 48.

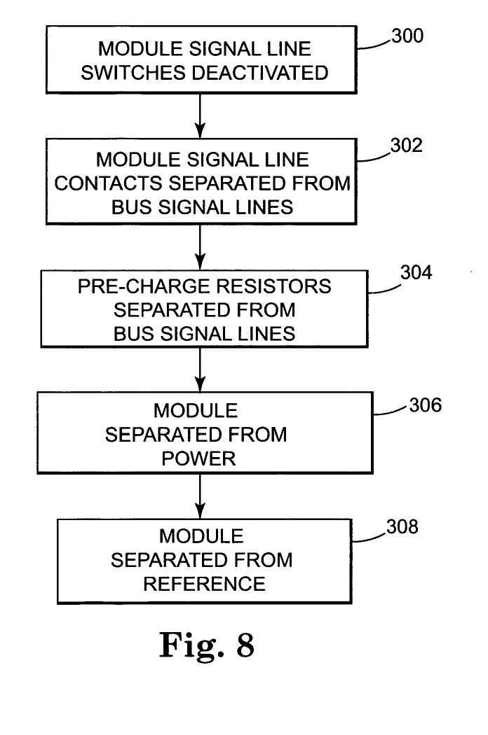

FIG. 8 is a flow diagram illustrating an exemplary removal of module 26 from bus 24. At 300, module 26 deactivates FET 86 and FET 98 to isolate module 26 from SDA and SCL signal lines 46 and 48. FET 86 and FET 98 provide high impedance drains to SDA and SCL signal lines 46 and 48. At this time, SDA contact 66 and module SDA contact 82 are at the voltage level on SDA signal line 46, and SCL contact 70 and module SCL contact 94 are at the voltage level on SCL signal line 48. At 302, as module 26 is removed from bus 24, module SDA contact 82 separates from SDA contact 66 and module SCL contact 94 separates from SCL contact 70. The voltage level on module SDA contact 82 remains equal to the voltage on SDA signal line 46, and the voltage level on module SCL contact 94 remains equal to the voltage level on SCL signal line 48.

At 304, module 26 is removed further from bus 24 and SDA pre-charge contact 64 is separated from module SDA pre-charge contact 80, and SCL pre-charge contact 68 is separated from module SCL pre-charge contact 92. At 306, module 26 is separated from power line contact 62 to remove power from module 26. The module 26 powers down and at 308, module 26 is separated from reference line contact 60 to completely remove module 26 from bus 24. Using connector 40, module 26 can be inserted onto and removed from a hot bus 24 without causing voltage glitches on the bus 24 and SDA and SCL signal lines 46 and 48.

1. A system comprising:
a bus comprising signal lines; and
a device configured to be inserted onto and removed from the bus through contacts configured to provide at different times during insertion and removal contact between a pre-charge circuit and one of the signal lines, and a low-impedance across the pre-charge circuit.

2. The system of claim 1, where the pre-charge circuit comprises a resistor located between one of the contacts and the device.

3. The system of claim 1, comprising a switch located between the contacts and the device.

4. The system of claim 3, where the switch is a field effect transistor located between the contacts and the device.

5. The system of claim 3, where the switch is configured to conduct after the low-impedance is provided across the pre-charge circuit.

6. The system of claim 1, comprising reference contacts configured to provide a common reference to the bus and the device before contact between the pre-charge circuit and one of the signal lines as the device is inserted onto the bus.

7. The system of claim 1, comprising power contacts and reference contacts, where the reference contacts are configured to provide a common reference to the bus and the device before the power contacts provide power, and the power contacts provide power before contact between the pre-charge circuit and one of the signal lines as the device is inserted onto the bus.

8. The system of claim 1, comprising power contacts and reference contacts, where the power contacts provide power before the reference contacts provide a common reference to the bus and the device, and the reference contacts provide a common reference to the bus and the device before contact between the pre-charge circuit and one of the signal lines as the device is inserted onto the bus.

9. The system of claim 1, comprising power contacts, where the power contacts are configured to provide power at the same time as contact between, the pre-charge circuit and one of the signal lines, as the device is inserted onto the bus.

10. The system of claim 1, where the signal lines comprise a serial data line and a serial clock line.

11. The system of claim 1, where the bus is an inter-integrated circuit bus.

12. A connector system, comprising:
a first connector; and
a second connector, where the first connector is configured to provide a first pre-charge circuit between the second connector and a first bus signal line, and the second connector is configured to provide a first short-circuit between the second connector and the first bus signal line, where the first connector and the second connector are staggered to provide the first pre-charge circuit and the first short-circuit at different times during engagement and disengagement of the connector system.

13. The connector system of claim 12, comprising:
a third connector; and
a fourth connector, where the third connector is configured to provide a second pre-charge circuit between the fourth connector and a second bus signal line, and the fourth connector is configured to provide a second short-circuit between the fourth connector and the second bus signal line, where the third connector and the fourth connector are staggered to provide the second pre-charge circuit and the second short-circuit at different times during engagement and disengagement of the connector system.

14. The connector system of claim 13, where the first connector and the third connector are staggered to simultaneously provide the first pre-charge circuit between the second connector and the first bus signal line and the second pre-charge circuit between the fourth connector and the second bus signal line.

15. The connector system of claim 13, where the first connector and the third connector are staggered to provide the first pre-charge circuit between the second connector and the first bus signal line and the second pre-charge circuit between the fourth connector and the second bus signal line in a sequence.

16. The connector system of claim 13, where the second connector and the fourth connector are staggered to simultaneously provide the first short-circuit between the second connector and the first bus signal line, and the second short-circuit between the fourth connector and the second bus signal line.

17. The connector system of claim 13, where the second connector and the fourth connector are staggered to provide the first short-circuit between the second connector and the first bus signal line, and the second short-circuit between the fourth connector and the second bus signal line in a sequence.

18. A module connector, comprising:
a first contact configured to connect a resistive load to a signal line; and
a second contact configured to provide a low-impedance to the signal line and across the resistive load.

19. The module connector of claim 18, where the first contact and the second contact are on different pins of the module connector.

20. The module connector of claim 18, where the first contact and the second contact are on the same pin of the module connector.

21. An electronic system, comprising:
means for equalizing the voltage on a signal line with the voltage on a device contact while maintaining the voltage on the signal line; and
means for shorting the signal line to the device contact after the voltage on the signal line equals the voltage on the device contact.

22. The electronic system of claim 21, where the means for equalizing comprises a resistor coupled between the device contact and the signal line.

23. The electronic system of claim 21, where the means for equalizing is in a parallel circuit configuration with the means for shorting after the device contact is shorted to the signal line.

24. The electronic system of claim 21, where the means for equalizing comprises a first connection and the means for shorting comprises a second connection configured to be staggered from the first connection to complete the first connection before completing the second connection as the signal line is coupled to the device contact.

25. The electronic system of claim 21, comprising means for buffering a device from the signal line before the voltage on the signal line equals the voltage on the device contact.

26. A method for hot coupling a device to a bus, comprising:
equalizing voltages on device contacts and corresponding bus signal lines;
maintaining the voltages on the corresponding bus signal lines as the voltages on the device contacts and the corresponding bus signal lines are equalized; and
connecting the device contacts to the corresponding bus signal lines.

27. The method of claim 26, comprising:
electrically coupling a device power line to a bus power line prior to equalizing voltages.

28. The method of claim 26, comprising:
electrically coupling a device reference line to a bus reference line prior to equalizing voltages.

29. The method of claim 28, where equalizing voltages and maintaining the voltages comprises:
electrically coupling a serial data line of the bus to one of the device contacts through a data line resistor; and
electrically coupling a serial clock line of the bus to another one of the device contacts through a clock line resistor.

30. The method of claim 29, comprising:
providing a data line switch;
providing a clock line switch;
activating the data line switch; and
activating the clock line switch.
